(19) United States
(12) Patent Application Publication
(10) Pub. No.: US 2021/0183930 A1
(43) Pub. Date: Jun. 17, 2021

(54) SOLID-STATE IMAGING DEVICE, DISTANCE MEASUREMENT DEVICE, AND MANUFACTURING METHOD

(71) Applicant: SONY SEMICONDUCTOR SOLUTIONS CORPORATION, Kanagawa (JP)

(72) Inventor: Yusuke TAKATSUKA, Kanagawa (JP)

(73) Assignee: SONY SEMICONDUCTOR SOLUTIONS CORPORATION, Kanagawa (JP)

(21) Appl. No.: 16/470,099

(22) PCT Filed: Dec. 12, 2018
(86) PCT No.: PCT/JP2018/045616

§ 371 Date: Jun. 14, 2019

(30) Foreign Application Priority Data
Dec. 26, 2017 (JP) 2017-248698

(51) Int. Cl. H01L 27/146

(52) U.S. Cl. CPC H01L 27/14623; H01L 27/14627; H01L 27/1464; H01L 27/14636; H01L 27/14605; H01L 27/1463; H01L 27/1461; H01L 27/14621; H01L 27/14685

(57) ABSTRACT

The present technology relates to a solid-state imaging device, a distance measurement device, and a manufacturing method that make it possible to improve condensing efficiency. Provided is a solid-state imaging device including: a pixel unit in which a plurality of pixels each having a light detection unit are arranged; a micro lens formed on a light incident surface side of the light detection unit for each of the pixels; and a light-shielding unit that is formed around the micro lens and shields light, wherein the micro lens is formed inside an opening part provided in the light-shielding part. The present technology is applicable to, for example, CMOS image sensors.

### TECHNICAL FIELD

The present technology relates to a solid-state imaging device, a distance measurement device, and a manufacturing method and, in particular, to a solid-state imaging device, a distance measurement device, and a manufacturing method that make it possible to improve condensing efficiency.

### BACKGROUND ART

The formation of a micro lense on each of solid-state imaging elements allows, for example, an improvement in light condensing efficiency or an improvement in sensitivity.

Patent Literature 1 discloses a method for manufacturing a lens array having a uniform curvature shape when seen from a two-dimensional direction while reducing the gap (non-lens portion) between adjacent micro lenses to a greater extent.

### CITATION LIST

### Patent Literature

Patent Literature 1: Japanese Patent Application Laid-open No. 2008-52004

### DISCLOSURE OF INVENTION

### Technical Problem

Meanwhile, there has been generally a demand for technologies for improving efficiency in condensing light incident on respective pixels in solid-state imaging elements.

The present technology has been made in view of the above circumstances and makes it possible to improve condensing efficiency.

### Solution to Problem

A solid-state imaging device according to an aspect of the present technology includes: a pixel unit in which a plurality of pixels each having a light detection unit are arranged; a micro lens formed on a light incident surface side of the light detection unit for each of the pixels; and a light-shielding unit that is formed around the micro lens and shields light, wherein the micro lens is formed inside an opening part provided in the light-shielding part.

A distance measurement device according to an aspect of the present technology includes: a pixel unit in which a plurality of pixels each having a light detection unit are arranged; a micro lens formed on a light incident surface side of the light detection unit for each of the pixels; and a light-shielding unit that is formed around the micro lens and shields light, wherein the micro lens has a light reception unit formed inside an opening part provided in the light-shielding part.

Note that the solid-state imaging device or the distance measurement device according to an aspect of the present technology may be a separate device or an internal block constituting one device.

A manufacturing method for a solid-state imaging device according to an aspect of the present technology includes: forming a pattern of a lens material inside an opening part provided in a light-shielding part; and forming a micro lens in a self-aligning manner with an inner wall of the opening part as a stopper when the lens material formed inside the opening part is subjected to thermal reflow to form the micro lens.

In a manufacturing method according to an aspect of the present technology, a pattern of a lens material is formed inside an opening part provided in a light-shielding part, and a micro lens is formed in a self-aligning manner with an inner wall of the opening part as a stopper when the lens material formed inside the opening part is subjected to thermal reflow to form the micro lens.

### Advantageous Effects of Invention

According to an aspect of the present technology, condensing efficiency can be improved.

Note that the effects described here are not necessarily limitative and any effect described in the present disclosure may be produced.

### BRIEF DESCRIPTION OF DRAWINGS

FIG. 1 is a substantial-part cross-sectional view showing a part of the structure of a solid-state imaging device according to a first embodiment.

FIGS. 2A and 2B are schematic views each showing a part of the structure of the solid-state imaging device according to the first embodiment.

FIGS. 3A and 3B are views each describing the flow of the manufacturing steps of the solid-state imaging device according to the first embodiment.

FIGS. 4A and 4B are views each describing the flow of the manufacturing steps of the solid-state imaging device according to the first embodiment.

FIGS. 5A and 5B are views each describing the flow of the manufacturing steps of the solid-state imaging device according to the first embodiment.

FIGS. 6A and 6B are views each describing the optical characteristics of a pixel of the solid-state imaging device according to the first embodiment.

FIGS. 7A and 7B are views each describing the flow of the manufacturing steps of a conventional solid-state imaging device.

FIGS. 8A and B are views each describing the flow of the manufacturing steps of the conventional solid-state imaging device.

FIGS. 9A and 9B are views each describing the flow of the manufacturing steps of the conventional solid-state imaging device.

FIGS. 10A and 10B are views each describing the flow of the manufacturing steps of the conventional solid-state imaging device.

FIGS. 11A and 11B are views each describing the optical characteristics of a pixel of a conventional solid-state imaging device.

FIGS. 12A and 12B are substantial-part plan views each showing a part of the structure of a solid-state imaging device according to a second embodiment.

FIGS. 13A and 13B are schematic views each showing a part of the structure of a solid-state imaging device according to a third embodiment.

FIGS. 14A and 14B are schematic views each showing a part of the structure of a solid-state imaging device according to a fourth embodiment.

FIG. 15 is a first substantial-part cross-sectional view showing a part of the structure of a solid-state imaging device according to a fifth embodiment.

FIG. 16 is a second substantial-part cross-sectional view showing a part of the structure of the solid-state imaging device according to the fifth embodiment.

FIG. 17 is a schematic view showing a part of the structure of the solid-state imaging device according to the fifth embodiment.

FIG. 18 is a schematic view showing a part of the structure of a solid-state imaging device according to a sixth embodiment.

FIG. 19 is a substantial-part cross-sectional view showing a part of the structure of a solid-state imaging device according to a seventh embodiment.

FIG. 20 is a view showing the configurations of a solid-state imaging device to which a technology related to the present disclosure is applied.

FIG. 21 is a diagram showing the configurations of a distance measurement device to which the technology related to the present disclosure is applied.

FIG. 22 is a diagram describing distance measurement using a TOF system.

FIG. 23 is a block diagram depicting an example of schematic configuration of a vehicle control system.

FIG. 24 is a diagram of assistance in explaining an example of installation positions of an outside-vehicle information detecting section and an imaging section.

### MODE(S) FOR CARRYING OUT THE INVENTION

Hereinafter, embodiments of the present technology will be described with reference to the drawings. Note that the description will be given in the following order.
1. First Embodiment: Basic structure
2. Second Embodiment: Structure in which opening parts are polygonal
3. Third Embodiment: Structure in which opening parts are arranged with interval thereof narrowed
4. Fourth Embodiment: Structure having RGB pixels and IR pixels
5. Fifth Embodiment: Structure in which light-shielding part is used as route wiring
6. Sixth Embodiment: Structure in which reflection preventing film is formed on light-shielding part
7. Seventh Embodiment: Structure in which light-shielding part is not provided between pixels
8. Modified Examples
9. Application Example to Solid-State Imaging Device
10. Application Example to Distance Measurement Device
11. Application Example to Mobile Bodies

### 1. First Embodiment

(Structure of Solid-State Imaging Device)

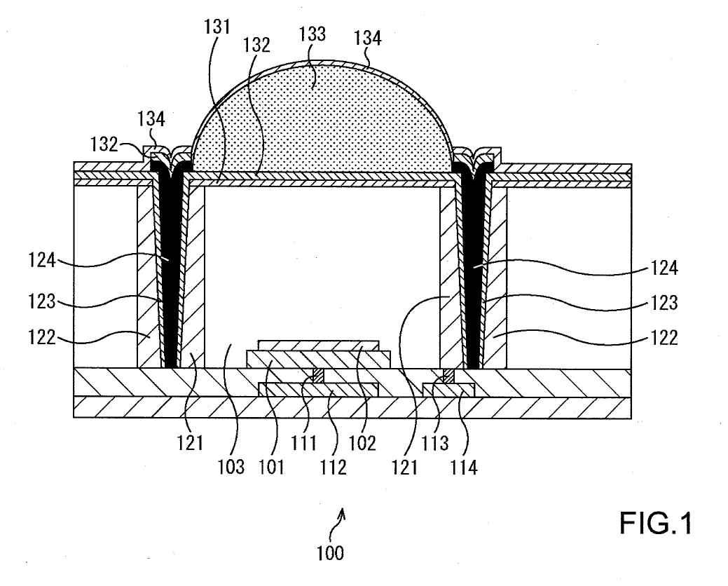

FIG. 1 is a substantial-part cross-sectional view showing a part of the structure of a solid-state imaging device according to a first embodiment. Hereinafter, the structure of the solid-state imaging device according to the first embodiment will be described with reference to the substantial-part cross-sectional view.

The solid-state imaging device according to the first embodiment has a pixel part (pixel region) in which a plurality of pixels 100 are two-dimensionally arranged. The pixel 100 is a pixel including an APD (Avalanche Photodiode) as a light detection unit (photoelectric conversion unit) for detecting a light signal. Here, the APD is a photodiode in which light-receiving sensitivity is improved using a phenomenon called avalanche multiplication.

The APD is used in a linear mode in which a reverse bias voltage is operated with a breakdown voltage or less or a Geiger mode in which the reverse bias voltage is operated with the breakdown voltage or more. In the Geiger mode, an avalanche phenomenon can occur even with the incidence of a single photon. Such a photodiode is called a SPAD (Single Photon Avalanche Diode).

The SPAD has an avalanche unit (multiplication region) inside a semiconductor region and has a structure in which an electron photoelectrically converted from one photon passes through the unit to be multiplied into tens of thousands of electrons. Hereinafter, the pixel 100 including the SPAD of the APD serving as a light detection unit in the structure of the solid-state imaging device according to the first embodiment will be described as an example.

In the pixel 100, an n-type semiconductor region 101 and a p-type semiconductor region 102 are formed inside a well layer 103. The well layer 103 is a low-concentration p-type or n-type semiconductor region. The n-type semiconductor region 101 is made of, for example, silicon and is a semiconductor region in which a conductivity type having high impurity concentration is an n-type. The p-type semiconductor region 102 is a semiconductor region in which a conductivity type having high impurity concentration is a p-type.

The p-type semiconductor region 102 constitutes pn-junction at the interface between the p-type semiconductor region 102 and the n-type semiconductor region 101. The p-type semiconductor region 102 has a multiplication region in which an electron (carrier) generated by the incidence of light to be detected is subjected to avalanche multiplication.

The n-type semiconductor region 101 functions as a cathode and is connected to wiring 112 such as copper (Cu) via a contact 111. An anode opposite to the cathode is, for example, formed in the same layer as the n-type semiconductor region 101, the anode being put in the place between the n-type semiconductor region 101 and (a light-shielding part 124) of separating regions for separating the SPAD or the like, and is connected to wiring 114 via a contact 113.

In FIG. 1, separating regions for separating the SPADs of adjacent pixels 100 are provided on both sides of the well layer 103. As the separating regions, groove parts (trenches) are formed between the p-type semiconductor region 121 and the p-type semiconductor region 122, and an insulating film 123 and the light-shielding part 124 are embedded in the groove parts.

An insulating film such as an oxide film and a nitride film can be, for example, used as the insulating film 123. Further, metal such as tungsten (W) and aluminum (Al) can be, for example, used as the light-shielding part 124. Note that an insulating film made of the same material as that of the insulating film 123 may be used to integrally form the insulating film 123 and the light-shielding part 124.

Further, an on-chip lens 133 is formed on the light incident surface side (on the light-receiving surface side) of the pixel 100. The on-chip lens 133 is a micro lens and can improve, for example, light condensing efficiency or sensitivity when formed on the pixel 100.

A reflection preventing film 131 and an insulating film 132 are formed between the on-chip lens 133 and the well layer 103. Further, a reflection preventing film 134 is also formed on the surface on the light incident surface side of the on-chip lens 133.

Here, the on-chip lens 133 is formed inside an opening part provided in the light-shielding part 124, and the light-shielding part 124 is formed around the on-chip lens 133. Note that the insulating film 132 and the reflection preventing film 134 are laminated at the upper part of the light-shielding part.

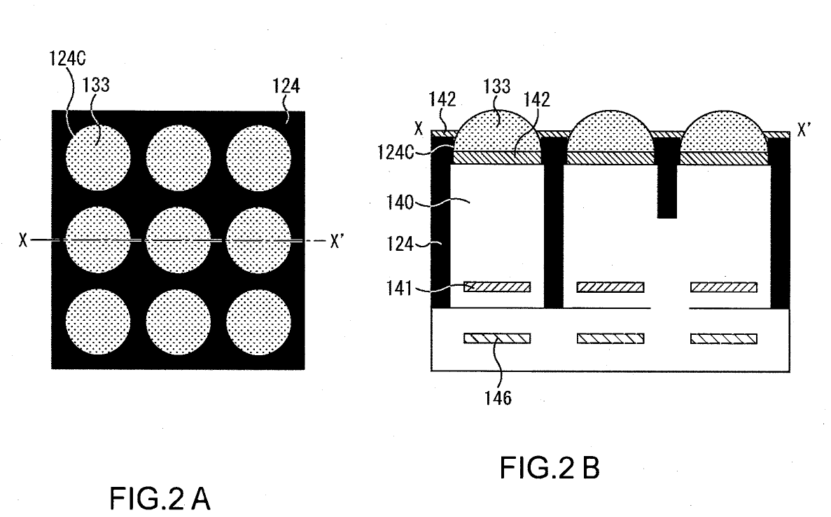

FIGS. 2A and 2B schematically show the structure of the on-chip lenses 133 formed inside opening parts 124C provided in the light-shielding part 124.

Note that since the pixels 100 are two-dimensionally arranged in the pixel region, FIG. 2A shows a plan view when seen from the light incident surface side corresponding to some pixels (3×3 pixels) among the plurality of pixels 100 arranged in the pixel region. Further, an X-X′ cross section in the plan view shown in FIG. 2A is shown in the cross-sectional view of FIG. 2B.

As shown in FIG. 2A, the opening part 124C having a circular shape is provided for each of the pixels 100 in the light-shielding part 124. The on-chip lens 133 is formed inside the opening part 124. As shown in FIGS. 2A and 2B, the on-chip lens 133 is a spherical lens (lens array) that is circular when seen from the light incident surface side and has a uniform curvature in a two-dimensional direction.

The on-chip lens 133 formed on the pixel 100 is a spherical lens having a uniform curvature in a two-dimensional direction as described above and is thus allowed to suppress aberration in a depth direction (laminated direction). As a result, condensing efficiency can be improved. Further, as will be described in detail later, particularly the pixel 100 including a SPAD is allowed to improve timing jitter characteristics.

Note that the solid-state imaging device (solid-state imaging element) shown in FIG. 1 and FIGS. 2A and 2B has a back-illuminated-type structure in which light is incident from the side of a substrate opposite to a side thereof on which a wiring layer is formed (from the back side of the substrate). Further, the cross-sectional view shown in FIG. 2B is a schematic view in which the cross-sectional view shown in FIG. 1 is simplified but is substantially the same in structure as the cross-sectional view of FIG. 1.

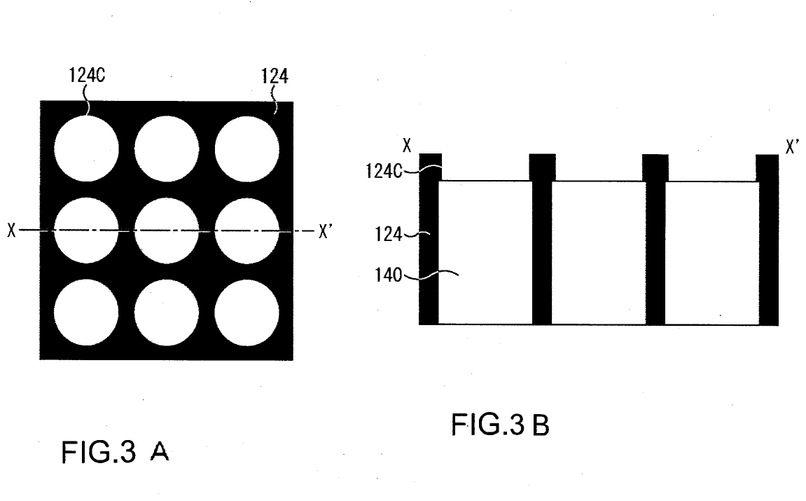

For example, in FIG. 2, a semiconductor region 140 corresponds to the well layer 103 of FIG. 1, and a multiplication region 141 corresponds to the multiplication region of the p-type semiconductor region 102 of FIG. 1. Further, a passivation film 142 corresponds to a protecting film such as the reflection preventing film 131 and the insulating film 132 of FIG. 1. In addition, wiring 146 corresponds to the wiring 112 or the like of FIG. 1. These corresponding relationships are also applied to other schematic views of FIGS. 3A and 3B to FIGS. 5A and 5B, FIGS. 6A and 6B, or the like.

(Flow of Manufacturing Steps)

Next, the flow of the manufacturing steps of the on-chip lens 133 formed for each of the pixels 100 of the solid-state imaging device according to the first embodiment will be described with reference to FIGS. 3A and 3B to FIGS. 5A and 5B.

Note that in FIGS. 3A and 3B to FIGS. 5A and 5B, part A in the respective figures shows a plan view when seen from the light incident surface side corresponding to some pixels (3×3 pixels) in the pixel region, and part B in the respective figures shows a cross-sectional view of an X-X′ cross section in the plan views shown in the part A of the respective figures.

First, as a first step, the light-shielding part 124 having the opening parts 124C is formed with respect to the semiconductor region 140 as shown in FIGS. 3A and 3B. Note that although omitted in the figures, the step of forming the passivation film 142 on the surface of the substrate, the step of forming a light detection unit such as a SPAD by the injection of impurities into the substrate (silicon), or the like is, for example, performed as a step previous to the step of forming the light-shielding part 124.

Here, for example, the substrate is engraved to form groove parts (trenches), and metal such as tungsten (W) is embedded in the groove parts. Besides, metal such as tungsten (W) is processed on the back surface side of the substrate so as to form circular openings. Thus, the light-shielding part 124 having the circular opening parts 124C is formed.

Note that an insulating film such as an oxide film and a nitride film may be, for example, used instead of metal such as tungsten (W) as the material of the light-shielding part 124.

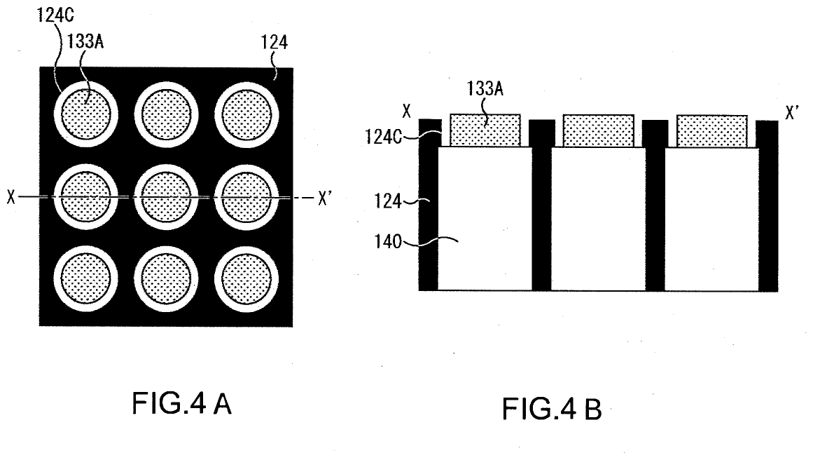

Then, as a second step, a photolithography step is performed as shown in FIGS. 4A and 4B to form the pattern of a cylindrical lens material 133A inside the opening parts 124C provided in the light-shielding part 124. Note that a resin material such as a photosensitive resin can be, for example, used as the material of the lens material 133A.

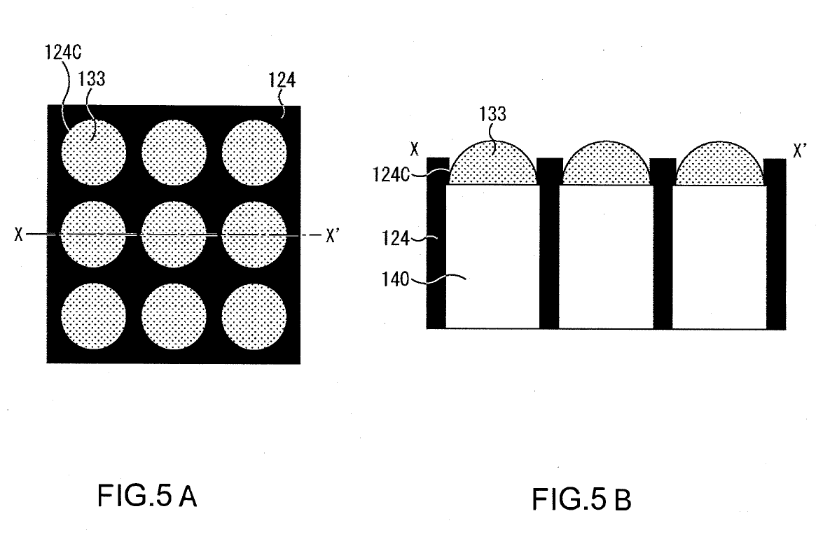

Next, as a third step, a thermal reflow step is performed as shown in FIGS. 5A and 5B. In the step, the lens material 133A formed inside the opening parts 124C is subjected to thermal reflow to form the semispherical on-chip lenses 133.

That is, when the cylindrical lens material 133A formed inside the circular opening parts 124C is subjected to thermal reflow, the lens material 133A melts and flows. However, the semispherical on-chip lenses 133 are formed in a so-called self-aligning manner by means of surface tension with the inner walls of the opening parts 124C as stoppers.

The on-chip lens 133 is formed for each of the pixels 100 and is a spherical lens (lens array) that is circular when seen from the light incident surface side and has a uniform curvature in a two-dimensional direction as shown in FIGS. 5A and 5B.

Through the manufacturing steps including the steps described above, the solid-state imaging device having the structure shown in FIG. 1 can be manufactured.

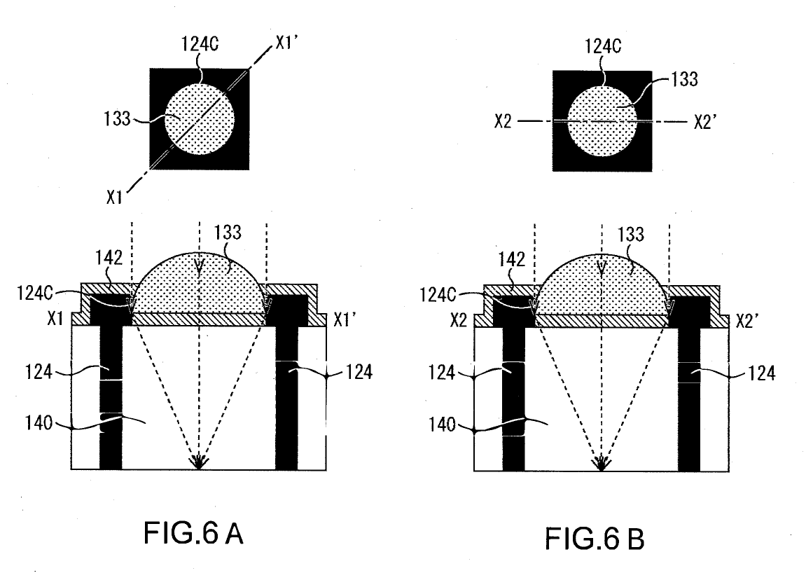

FIGS. 6A and 6B show the optical characteristics of the pixel 100 of the solid-state imaging device according to the first embodiment. Here, when the on-chip lens 133 is seen from the light incident surface side, an X1-X1′ cross section in its oblique direction is shown in the cross-sectional view of FIG. 6A, while an X2-X2′ cross section in its lateral direction is shown in the cross-sectional view of FIG. 6B.

In the solid-state imaging device manufactured by the manufacturing steps described above, the on-chip lens 133 formed for each of the pixels 100 is a spherical lens having a uniform curvature in a two-dimensional direction. Therefore, the X1-X1′ cross section shown in FIG. 6A and the X2-X2′ cross section shown in FIG. 6B are the same cross sections, and incident light (light to be detected) shown by dotted lines in the figures is condensed into the same point (condensing points are coincident with each other). Thus, aberration in a depth direction can be suppressed.

As described above, aberration in the depth direction in each of the pixels 100 is eliminated in the solid-state imaging device according to the first embodiment, whereby an improvement in condensing efficiency is allowed.

Note that the lens width and the lens thickness of the on-chip lens 133 are actually designed according to its refractive index so as to have a curvature (almost) close to that of a semisphere. The curvature of the lens is adjusted so that the light to be detected falls within the multiplication region 141 and also falls within a metal reflecting plate (the wiring 146) provided under the multiplication region 141. That is, the light is condensed with a condensing diameter so as to fall within the wiring of a first layer widely formed under a light detection unit, whereby the light is reflected by the metal reflecting plate (the wiring 146) and can be more efficiently taken.

Here, for example, when the solid-state imaging device according to the first embodiment is applied to a distance measurement device (for example, a distance measurement device such as a TOF (Time Of Flight) type sensor), an improvement in timing jitter characteristics is one of significant factors for improving accuracy in distance measurement in the pixel 100 including a SPAD.

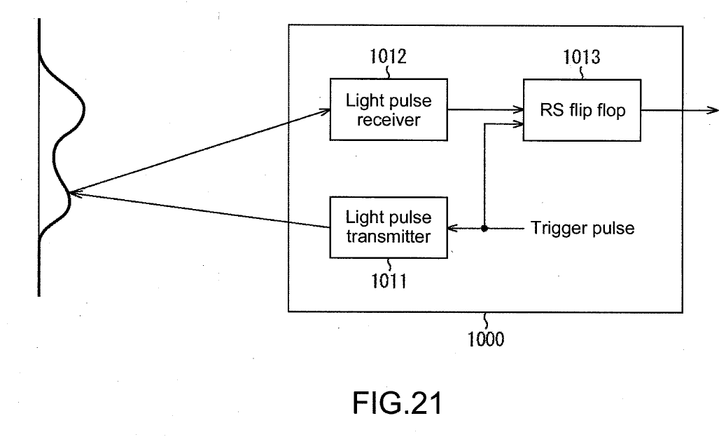

Specifically, as shown in FIG. 21 that will be described later, a TOF type sensor measures time until light emitted from the sensor itself reflects and returns after coming into contact with an object to measure a distance to the object. When the solid-state imaging device according to the first embodiment is used, photons are generated as reflected light (light to be detected) is received by the pixel 100 including a SPAD.

On this occasion, avalanche multiplication occurs in the pixel 100 when electrons generated by the incidence of one photon are carried to the multiplication region 141. However, for example, if the generated position of the electrons is a region at the end of the semiconductor region 140 of the pixel 100, it takes time to carry the electrons to the multiplication region 141. Like this, if there are variations in the time until the electrons are carried to the multiplication region 141 (variations in photoelectric conversion unit), the amplitude of timing jitter becomes large (for example, the electrons generated in a region at the end of the semiconductor region 140 of the pixel 100 causes an error).

With consideration given to the above fact, the on-chip lens 133 formed for each of the pixels 100 is formed into a spherical lens (lens array) having a uniform curvature in a two-dimensional direction in the solid-state imaging device according to the first embodiment to make condensing points coincident with each other in a depth direction to suppress aberration in the depth direction and suppress variations in time until electrons are carried to the multiplication region 141 (variations in photoelectric conversion unit).

That is, since the condensing of light into the multiplication region 141 becomes uniform, variations in time until photoelectrically-converted electrons are subjected to avalanche multiplication can be suppressed. As a result, when the solid-state imaging device according to the first embodiment is applied to a distance measurement device, the pixel 100 including a SPAD is allowed to improve accuracy in distance measurement with an improvement in timing jitter characteristics.

Further, in the solid-state imaging device according to the first embodiment, the on-chip lenses are not formed by etching-back transfer but are formed by thermal reflow at portions surrounded by the opening parts 124C of the light-shielding part 124. Therefore, the lenses can have a part having a curvature at a position lower than the light-shielding part 124, and can suppress cross talk from the light incident surface side (on the light receiving surface side).

In addition, the on-chip lenses 133 are formed inside the opening parts 124C of the light-shielding part 124 in the solid-state imaging device according to the first embodiment. Therefore, a short circuit between the on-chip lenses can be suppressed during manufacturing. Therefore, the on-chip lenses can be formed with high productivity.

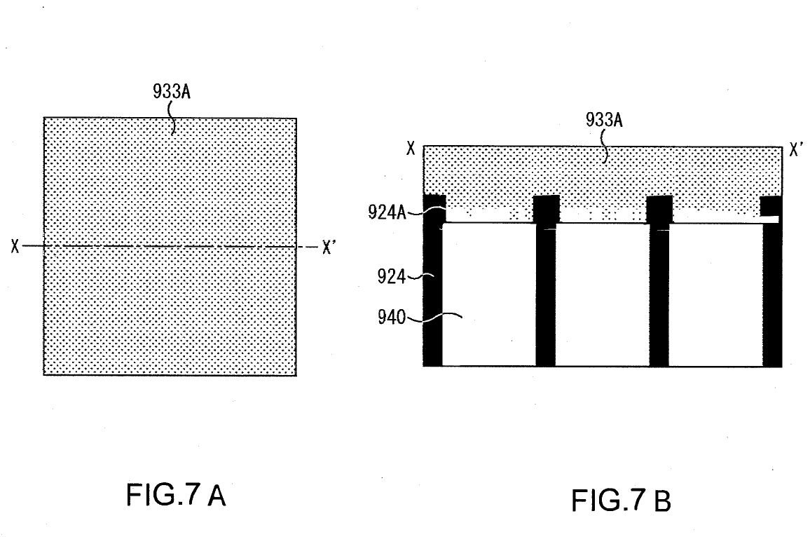

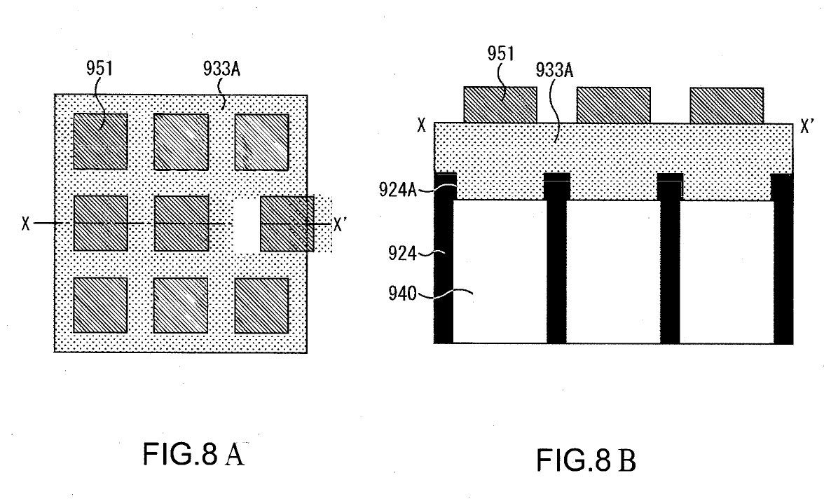

Note that FIGS. 7A and 7B to FIGS. 10A and 10B show the flow of the manufacturing steps of a conventional on-chip lens for comparison. In the conventional manufacturing steps, a lens material 933A is first laminated on a semiconductor region 940 in which a light-shielding part 924 is embedded as a first step (FIGS. 7A and 7B). Next, the pattern of a rectangular resist material 951 is formed on the lens material 933A as a second step (FIGS. 8A and 8B).

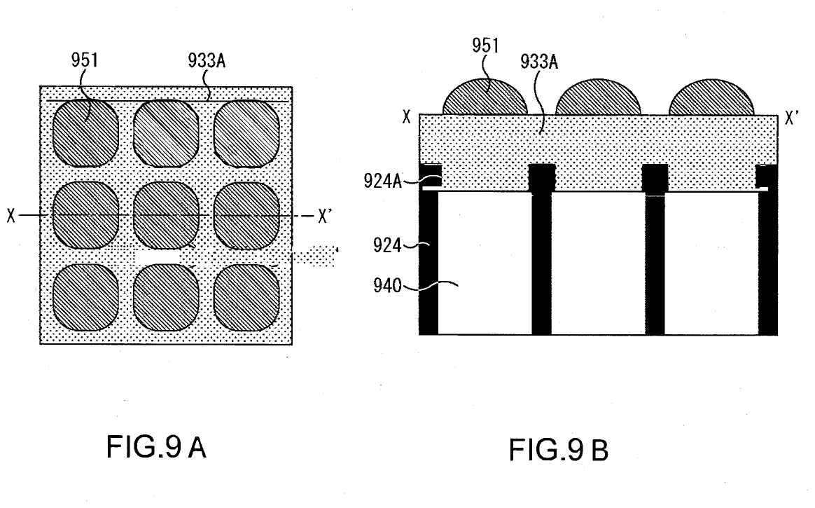

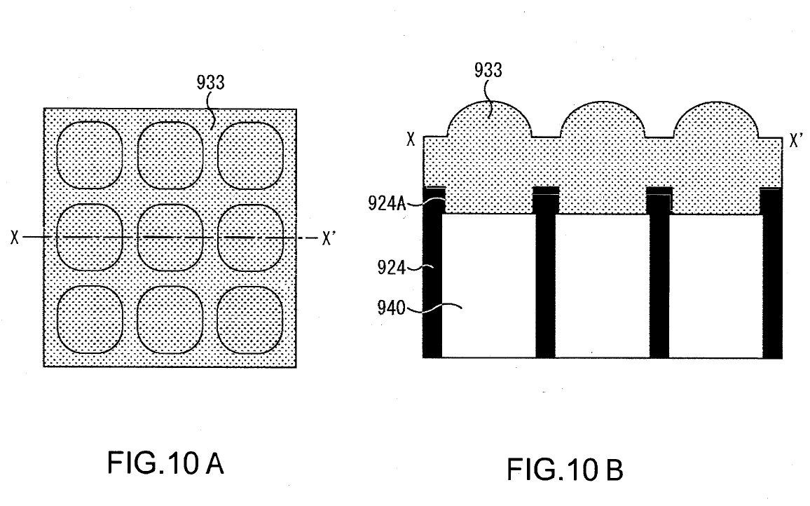

Then, the shape of the resist material 951 is deformed by thermal reflow into a square shape of which the corners are round when seen from a light incident surface side as a third step (FIGS. 9A and 9B). Then, the pattern of the resist material 951 is removed to form an on-chip lens 933 as a fourth step (FIGS. 10A and 10B).

The on-chip lens 933 is formed for each pixel and formed into a square lens (lens array) of which the corners are round when seen from the light incident surface side as shown in FIG. 10A. Further, as shown in FIG. 10B, the on-chip lens 933 is formed to include not only a semispherical part on the light incident surface side but also a flat part on a surface side opposite to the light incident surface side.

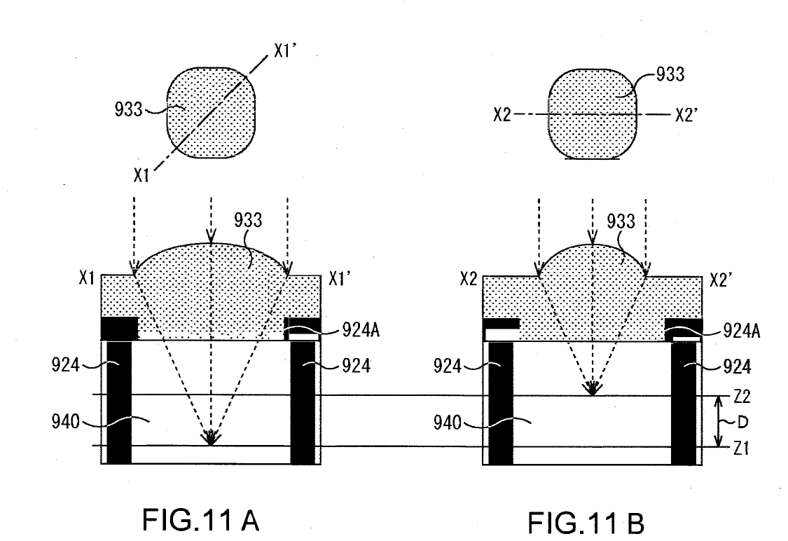

Here, FIGS. 11A and 11B show the optical characteristics of a pixel of a conventional solid-state imaging device. Like FIGS. 6A and 6B described above, when an on-chip lens 933 is seen from a light incident surface side, an X1-X1′ cross section in its oblique direction is shown in the cross-sectional view of FIG. 11A, while an X2-X2′ cross section in its lateral direction is shown in the cross-sectional view of FIG. 11B.

In a solid-state imaging device manufactured by the conventional manufacturing steps described above, the on-chip lens 933 formed for each pixel is a square lens of which the corners are round when seen from the light incident surface side. Therefore, the X1-X1′ cross section shown in FIG. 11A and the X2-X2′ cross section shown in FIG. 11B are different cross sections, and incident light (light to be detected) shown by dotted lines in the figures is condensed into different points (condensing points are not coincident with each other).

That is, the X1-X1′ cross section and the X2-X2′ cross section have different widths in a lateral direction in the figures even in the same on-chip lens 933, and thus light is condensed at different positions Z1 and Z2 in the depth direction. Thus, in the conventional solid-state imaging device, the on-chip lens 933 is not formed into a spherical lens having a uniform curvature in a two-dimensional direction unlike the on-chip lens 133 (FIGS. 6A and 6B) described above. Therefore, aberration occurs due to a difference D between the condensing positions (Z1 and Z2) in the depth direction.

Therefore, since condensing efficiency cannot be improved due to the occurrence of aberration in the depth direction in the conventional solid-state imaging device, timing jitter characteristics cannot be improved. Further, since the on-chip lens 933 has a part having a curvature at a position higher than the light-shielding part 924 in the conventional solid-state imaging device, the suppression of cross talk becomes difficult.

In the solid-state imaging device according to the first embodiment, a photosensitive resin is patterned into a cylindrical shape and subjected to thermal reflow at the circular opening parts 124C provided in the light-shielding part 124 as described above to form spherical lenses (lens array) having a uniform curvature in a two-dimensional direction in a self-aligning manner. Thus, it becomes possible to suppress aberration in the depth direction at the time of forming the on-chip lens 133 for each of the pixels 100. As a result, condensing efficiency can be improved.

Note that the pixel 100 including a SPAD can realize a large-scale array structure according to a semiconductor integrated technology such as a CMOS (Complementary Metal Oxide Semiconductor) process technology in the solid-state imaging device according to the first embodiment. That is, the solid-state imaging device according to the first embodiment can be configured as, for example, a CMOS image sensor.

### 2. Second Embodiment

(Structure of Solid-State Imaging Device)

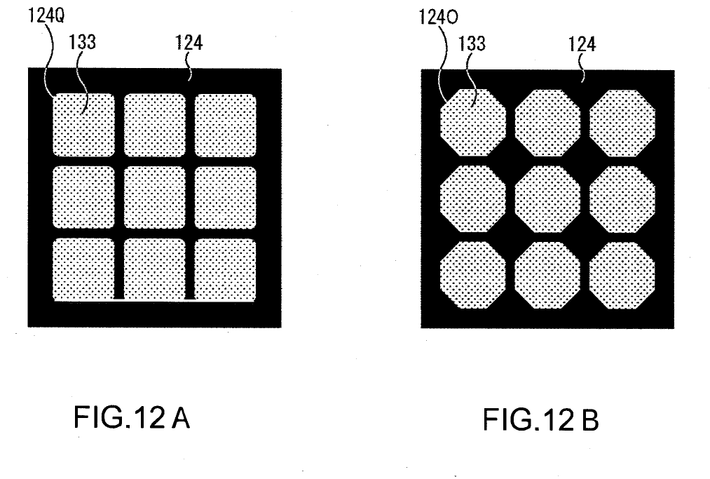

FIGS. 12A and 12B are substantial-part plan views each showing a part of the structure of a solid-state imaging device according to a second embodiment. Hereinafter, the structure of the solid-state imaging device according to the second embodiment will be described with reference to the substantial-part plan views.

The solid-state imaging device according to the first embodiment described above shows the case in which the shape of the opening parts 124C of the light-shielding part 124 is formed into a circular shape and thus the semispherical on-chip lenses 133 are formed in a self-aligning manner with the inner walls of the opening parts 124C as stoppers. However, the shape of the opening parts provided in the light-shielding part 124 may be any shape other than a circular shape such as, for example, a polygonal shape.

### First Example

FIG. 12A shows a structure in which opening parts 124Q having a square shape are provided in a light-shielding part 124.

In FIG. 12A, when the solid-state imaging device according to the second embodiment is manufactured, the pattern of a lens material 133A such as a photosensitive resin is formed inside the opening parts 124Q in a photolithography step and then the lens material 133A formed inside the opening parts 124Q is subjected to thermal reflow in a thermal reflow step.

As a result, the lens material 133A melts and flows. However, on-chip lenses 133 are formed in a self-aligning manner with the inner walls of the opening parts 124Q having a square shape as stoppers. The on-chip lenses 133 are lenses (lens array) having a square shape when seen from a light incident surface side.

### Second Example

FIG. 12B shows a structure in which opening parts 124O having an octagonal shape are provided in the light-shielding part 124.

In FIG. 12B, when the solid-state imaging device according to the second embodiment is manufactured, the lens material 133A is formed inside the opening parts 124O and then subjected to thermal reflow. As a result, the lens material 133A melts and flows. However, the on-chip lenses 133 are formed in a self-aligning manner with the inner walls of the opening parts 124O having an octagonal shape as stoppers. The on-chip lenses 133 are lenses (lens array) having an octagonal shape when seen from a light incident surface side.

In the solid-state imaging device according to the second embodiment, the on-chip lenses 133 can be formed in a self-aligning manner with the inner walls of opening parts as stoppers even in a case in which a polygonal shape such as a square shape and an octagonal shape is, for example, employed as the shape of the openings provided in the light-shielding part 124 as described above. Note that a polygonal shape such as a square shape and an octagonal shape is exemplified here as the shape of the openings part other than a circular shape but any other shape may be employed.

### 3. Third Embodiment

(Structure of Solid-State Imaging Device)

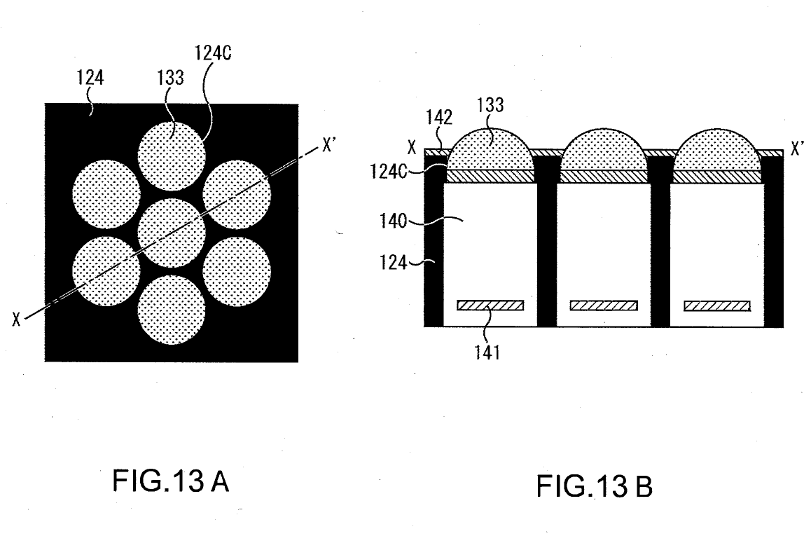

FIGS. 13A and 13B are schematic views each showing a part of the structure of a solid-state imaging device according to a third embodiment. Hereinafter, the structure of the solid-state imaging device according to the third embodiment will be described with reference to the schematic views. Note that FIGS. 13A and 13B show a plan view of some pixels in a pixel region and a cross-sectional view of an X-X′ cross section, respectively.

The solid-state imaging device according to the first embodiment described above shows the case in which the opening parts 124C are provided in the light-shielding part 124 at even intervals (with a fixed gap placed therebetween) in a matrix direction when seen from the light incident surface side. However, the arrangement of opening parts 124C provided in the light-shielding part 124 may be an arrangement including the combination of arrays having a prescribed shape according to a fixed rule.

For example, as shown in FIGS. 13A and 13B, an arrangement including the combination of arrays having a hexagonal shape can be provided in such a manner that the gap between respective pixels 100 in a pixel region is reduced to a greater extent and seven pixels 100 are bundled together. In this case, the arrangement of the opening parts 124C in the light-shielding part 124 are the arrangement in which the seven opening parts 124C are bundled together to combine arrays having a hexagonal shape (structure in which the opening parts 124C are most densely filled to have a hexagonal shape) so as to correspond to the arrays of the pixels 100.

By the employment of such an arrangement, it becomes possible to narrow the gap between the on-chip lenses 133 as shown in FIG. 13A. As a result, a larger number of the opening parts can be provided in the light-shielding part 124.

Here, when the solid-state imaging device according to the third embodiment is manufactured, the pattern of a lens material 133A is formed inside the opening parts 124C arrayed in a hexagonal shape in a photolithography step and then the lens material 133A formed inside the opening parts 124C is subjected to thermal reflow in a thermal reflow step.

As a result, the lens material 133A melts and flows. However, on-chip lenses 133 are formed in a self-aligning manner with the inner walls of the opening parts 124C as stoppers. The on-chip lenses 133 are spherical lenses having a uniform curvature in a two-dimensional direction.

Note that FIGS. 13A and 13B show the example in which the opening parts 124C are arrayed in a hexagonal shape for every seven opening parts 124C (in other words, it can be said that the opening parts 124C of even-number lines or odd-number lines are shifted by half a pitch in a line direction) to narrow the gap between the on-chip lenses 133. However, the opening parts 124C in the light-shielding part 124 may be arranged by the combination of arrays having a prescribed shape according to another rule.

In the solid-state imaging device according to the third embodiment, the arrangement of the opening parts 124C provided in the light-shielding part 124 is an arrangement including the combination of arrays having a prescribed shape according to a fixed rule as described above. Thus, the gap between the on-chip lenses 133 is narrowed, and a larger number of the opening parts 124C can be provided in the light-shielding part 124 (the opening parts can be arrayed without causing waste). As a result, an opening ratio can be increased. Therefore, detection efficiency called PDE (Photon Detection Efficiency) can also be improved.

### 4. Fourth Embodiment

The solid-state imaging device according to the first embodiment described above shows the pixel 100 including the avalanche photodiode (APD) or the single photon avalanche photodiode (SPAD) as a light detection unit (photoelectric conversion unit) but may include a photodiode (PD) as a light detection unit (photoelectric conversion unit).

As pixels 100 including photodiodes (PDs), R pixels, G pixels, and B pixels can be, for example, arranged with an array pattern such as a Bayer array by the provision of a color filter between on-chip lenses 133 and the photodiodes (PDs).

Here, the R pixels are pixels that obtain charges corresponding to the light of a red (R) component from light passing through the color filter that causes the wavelength component of red (R) to pass therethrough. Further, the G pixels are pixels that obtain charges corresponding to the light of a green (G) component from light passing through the color filter that causes the wavelength component of green (G) to pass therethrough. The B pixels are pixels that obtain charges corresponding to the light of a blue (B) component from light passing through the color filter that allows the wavelength component of blue (B) to pass therethrough.

Note that the Bayer array is an array pattern in which the G pixels are arrayed in a checkered pattern and the R pixels and B pixels are alternately arrayed every other line in the remaining portions. Further, here, pixels other than the RGB pixels such as W pixels corresponding to white (W) and IR pixels corresponding to infrared (IR) may be, for example, included.

However, the W pixels are not required to have the color filter provided thereon. Specifically, pixels not coated with the color filter or pixels coated with a material having high transmittance in all visible light regions instead of the color filter are the W pixels. That is, the W pixels cause light in all wavelength regions to pass therethrough, while the other RGB pixels (for example, the R pixels or B pixels) cause only a specific wavelength to pass therethrough. Further, the IR pixels are pixels that cause infrared (IR) to pass therethrough and have sensitivity to the wavelength band of infrared light.

(Structure of Solid-State Imaging Device)

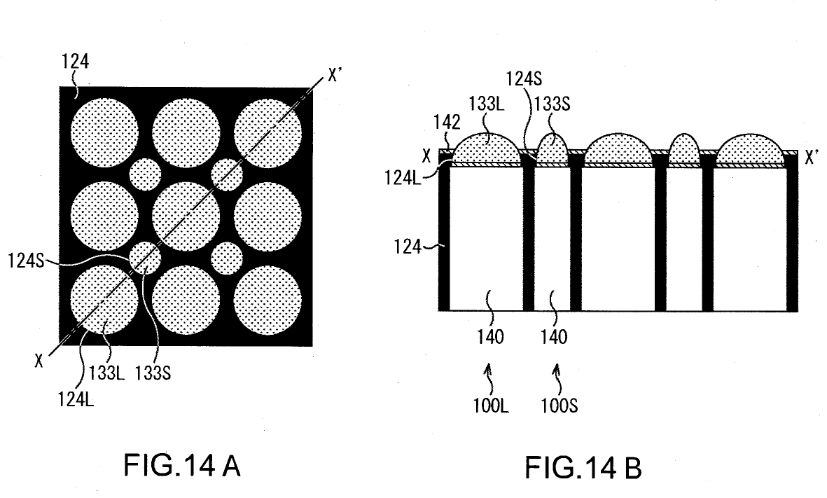

FIGS. 14A and 14B are schematic views each showing a part of the structure of a solid-state imaging device according to a fourth embodiment. Hereinafter, the structure of the solid-state imaging device according to the fourth embodiment will be described with reference to the schematic views. Note that FIGS. 14A and 14B show a plan view of some pixels in a pixel region and a cross-sectional view of an X-X′ cross section, respectively.

As shown in FIG. 14A, when opening parts 124L are provided at even intervals (with a fixed gap placed therebetween) in a matrix direction in a light-shielding part 124, opening parts 124S are provided in the region of the gap. In FIG. 14A, one opening part 124S is provided for each region including the central position of four opening parts 124L. Note that the opening parts 124S have a circular shape like the opening parts 124L but have a diameter smaller than that of the opening parts 124L.

Here, when the solid-state imaging device according to the fourth embodiment is manufactured, a lens material 133A corresponding to the diameters of the respective opening parts is formed inside each of the opening parts 124L and the opening parts 124S in a photolithography step and then each of the lens material 133A formed inside the opening parts 124L and the opening parts 124S formed inside the opening parts 124S is subjected to thermal reflow in a thermal reflow step.

As a result, the lens material 133A melts and flows. However, on-chip lenses 133L are formed in a self-aligning manner with the inner walls of the opening parts 124L as stoppers, and on-chip lenses 133S are formed in a self-aligning manner with the inner walls of the opening parts 124S as stoppers. Both the on-chip lenses 133L and 133S are spherical lenses having a uniform curvature in a two-dimensional direction, but the diameter of the on-chip lenses 133S is smaller than that of the on-chip lenses 133L.

Further, here, as shown in FIG. 14B, pixels 100L corresponding to the on-chip lenses 133L can be R pixels, G pixels, or B pixels, and pixels 100S corresponding to the on-chip lenses 133S can be IR pixels. That is, in the example of FIGS. 14A and 14B, one IR pixel is provided for four RGP pixels.

In the solid-state imaging device according to the fourth embodiment described above, pixels such as R pixels, G pixels, B pixels, and the IR pixels can be arranged with a prescribed array pattern as the pixels 100 (100L and 100S). In this manner, even pixels including the photodiodes (PDs) instead of avalanche photodiodes (APDs) or single photon avalanche photodiodes (SPADs) can make the on-chip lenses 133 formed corresponding to the respective pixels 100 into spherical lenses having a uniform curvature in a two-dimensional direction.

Therefore, since aberration in a depth direction is eliminated, condensing efficiency can be improved as described above. Further, the on-chip lenses 133L and 133S are formed by thermal reflow at portions surrounded by the opening parts 124L and 124S of the light-shielding part 124, whereby the lenses can have a part having a curvature at a position lower than the light-shielding part 124. Therefore, color mixture from a light incident surface side (light receiving surface side) can be suppressed.

In addition, in the example of the pattern of the layout shown in FIG. 14A, the IR pixels are arranged in the space (region) generated when the RGB pixels are arranged with a prescribed array pattern. Therefore, an opening ratio can be increased with a reduction in ineffective region.

Note that the solid-state imaging device according to the fourth embodiment can be configured not only as CMOS image sensor but also as, for example, a CCD (Charge Coupled Device) image sensor or the like. Further, like the third embodiment, the arrangement of the pixels 100 such as R pixels, G pixels, and B pixels may be an arrangement in which arrays having a prescribed shape according to a fixed rule are combined together (for example, a structure in which the pixels 100 are most densely filled to have a hexagonal shape).

### 5. Fifth Embodiment

(Structure of Solid-State Imaging Device)

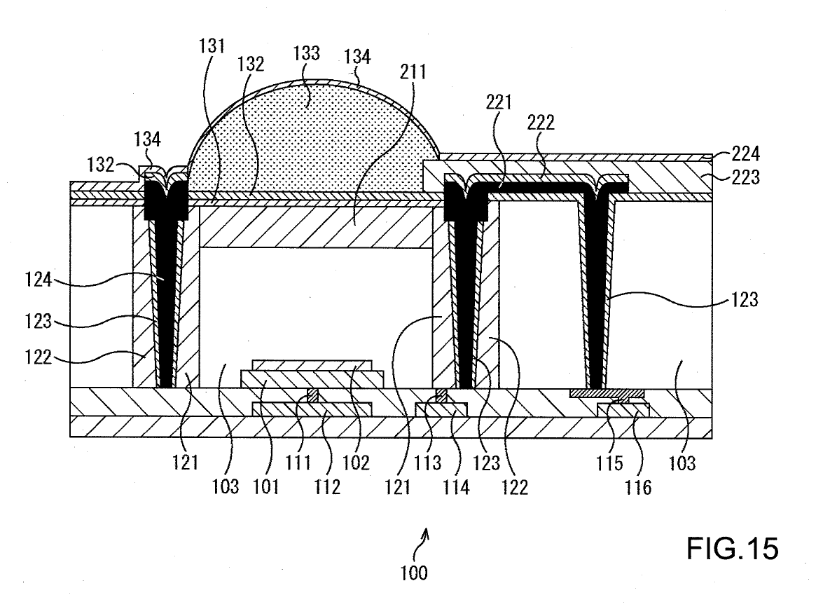

FIG. 15 is a substantial-part cross-sectional view showing a part of the structure of a solid-state imaging device according to a fifth embodiment. Hereinafter, the structure of the solid-state imaging device according to the fifth embodiment will be described with reference to the substantial-part cross-sectional view.

In the solid-state imaging device according to the fifth embodiment, a light-shielding part 124 is used as route wiring on a light incident surface side when metal such as, for example, tungsten (W) and aluminum (Al) is used as the material of the light-shielding part 124 embedded in separating regions for separating SPADs.

That is, in FIG. 15, a light-shielding part 221 is formed in such a manner that metal such as tungsten (W) is embedded in a groove part formed in a separating region on the right side of a pixel 100 and metal such as tungsten (W) is embedded in a well layer 103 on the right side of the separating region through a through-via and connected to the metal embedded in the separating region on the right side.

On the upper part of the light-shielding part 221, an oxide film 222, a light-shielding film 223, and a reflection preventing film 224 are laminated. Further, the light-shielding part 221 is connected to wiring 116 via a contact 115.

Further, in FIG. 15, an anode contact is dropped in the light-shielding part 124 to form a p-type anode contact region 211. Thus, it becomes possible to apply an electric field to the multiplication region of a p-type semiconductor region 102 from above in the figure. In the solid-state imaging device according to the fifth embodiment, the light-shielding parts 124 and 221 are used as the route wiring of the anode contact while performing a light-shielding function as described above, whereby a common anode can be dropped with respect to the SPADs of pixels 100.

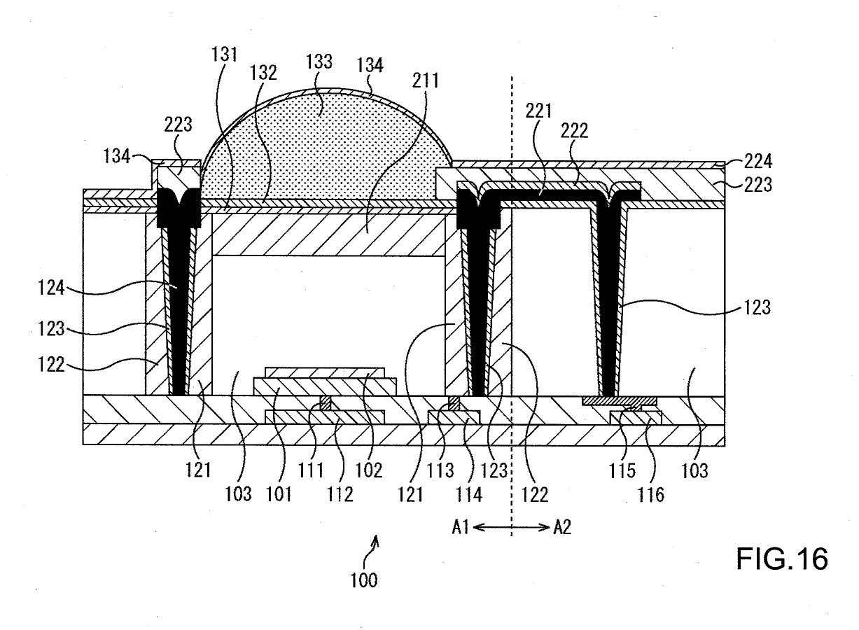

Further, in the structure shown in FIG. 15, the light-shielding film 223 is formed only on the upper part of the light-shielding part 221 used as the route wiring. However, as shown in FIG. 16, the light-shielding film 223 may be formed on the upper part of the light-shielding part 124. Note that the light-shielding film 223 may be made of the same material as that of the light-shielding part 124 to be integrally formed with the light-shielding part 124. Further, an oxide film may be formed between the light shielding part 124 and the light-shielding film 223.

Here, in FIG. 16, the left side of a dotted line in the figure shows a pixel region A1, and the right side thereof shows a peripheral region A2. That is, it can be said that the light-shielding film 223 on the left side of the dotted line is a pixel-region light-shielding film, and that the light-shielding film 223 on the right side of the dotted line is a peripheral-region light-shielding film.

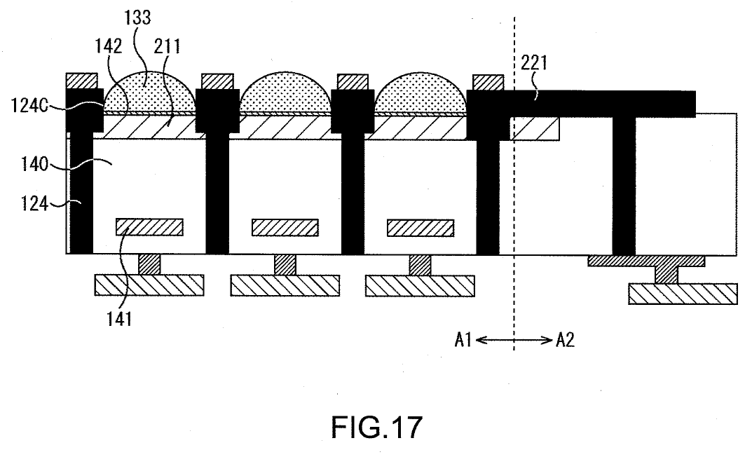

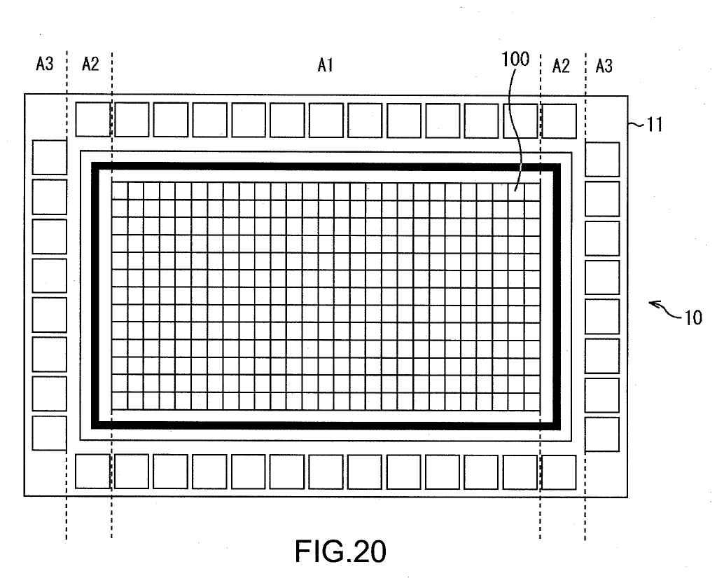

Note that a plurality of pixels 100 are actually two-dimensionally arranged in the pixel region A1. Therefore, the light-shielding part 221 used as the route wiring is formed in a region including the boundary between the pixel region A1 and the peripheral region A2 as shown in FIG. 17. The details of the relationship between the pixel region A1 and the peripheral region A2 will be described later with reference to FIG. 20.

In the solid-state imaging device according to the fifth embodiment described above, the light-shielding parts 124 and 221 are used also as the route wiring of the anode contact, and a contact is dropped in the SPADs of the respective pixels 100, whereby a common anode can be dropped with respect to the SPADs of the respective pixels 100.

### 6. Sixth Embodiment

(Structure of Solid-State Imaging Device)

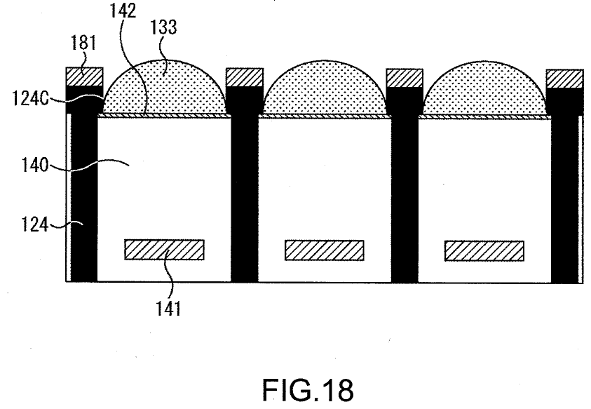

FIG. 18 is a schematic view showing a part of the structure of a solid-state imaging device according to a sixth embodiment. Hereinafter, the structure of the solid-state imaging device according to the sixth embodiment will be described with reference to the schematic view.

As shown in FIG. 18, a reflection preventing film 181 is formed (deposited) on the upper part of a light-shielding part 124 formed in separating regions for separating the SPADs of adjacent pixels 100 in the solid-state imaging device according to the sixth embodiment. Here, for example, there is apprehension that reflection becomes large on the surface of the light-shielding part 124 when metal such as tungsten (W) and aluminum (Al) is used as the material of the light-shielding part 124. In order to address this, a reflection preventing film 181 is coated on the light-shielding part 124 to suppress the reflection of the surface.

Note that the other embodiments described above also show the structure in which the reflection preventing film is deposited. Here, in order to explicitly show the effect of the reflection preventing film formed on the upper part of the light-shielding part 124, the structure is shown in the cross-sectional view of FIG. 18 as another embodiment.

As described above, the reflection of light on the upper surface of the light-shielding part 124 can be reduced with the reflection preventing film 181 formed on the upper part of the light-shielding part 124 in the solid-state imaging device according to the sixth embodiment. Therefore, cross talk due to reflected light can be suppressed. Further, influence by flare can be reduced.

### 7. Seventh Embodiment

(Structure of Solid-State Imaging Device)

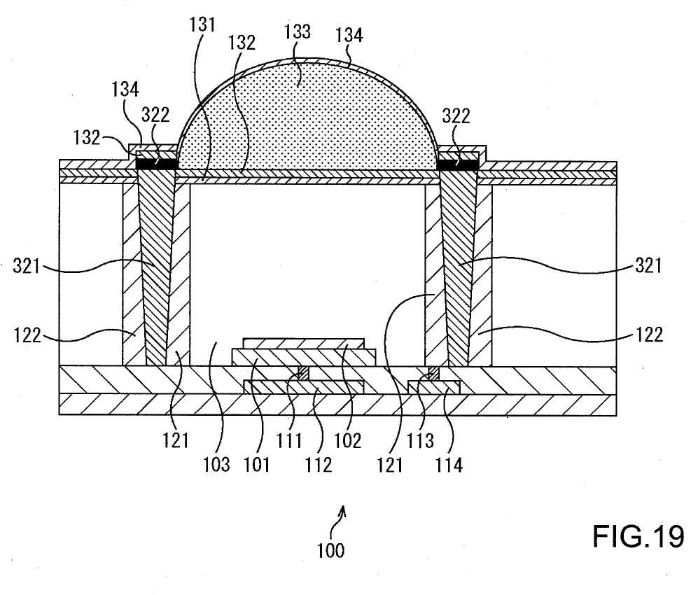

FIG. 19 is a substantial-part cross-sectional view showing a part of the structure of a solid-state imaging device according to a seventh embodiment. Hereinafter, the structure of the solid-state imaging device according to the seventh embodiment will be described with reference to the substantial-part cross-sectional view.

The solid-state imaging device according to the first embodiment described above shows the structure in which the light-shielding part 124 is formed in the separating regions between the pixels 100. However, a structure in which the light-shielding part 124 is not provided may be employed.

As shown in FIG. 19, an oxide film 321 is embedded in groove parts (trenches) formed in p-type semiconductor regions 121 and 122 as separating regions for separating the SPADs of adjacent pixels 100 on both sides of a well layer 103 in the solid-state imaging device according to the seventh embodiment. Further, a light-shielding part 322 is formed on the upper part of the oxide film 321. In the light-shielding part 322, an opening part having a circular shape is provided for each pixel 100.

Here, when the solid-state imaging device according to the seventh embodiment is manufactured, the pattern of a lens material 133A is formed inside the opening parts of the light-shielding part 322 in a photolithography step and then the lens material 133A is subjected to thermal reflow in a thermal reflow step. Thus, spherical on-chip lenses 133 having a uniform curvature in a two-dimensional direction are formed in a self-aligning manner.

In the solid-state imaging device according to the seventh embodiment described above, the on-chip lenses 133 can be formed in a self-aligning manner with the inner walls of the light-shielding part 322 formed on the upper part of the oxide film 321 as stoppers even when the oxide film 321 is embedded in the groove parts (trenches) formed in the separating regions instead of the light-shielding part 124.

### 8. Modified Examples

(Examples of Other Structures)

In the first embodiment or the like described above, a hole accumulation region for accumulating holes may be formed between the separating regions for separating the SPADs and the well layer 103 (on the lateral walls of the separating regions). Alternatively, in the first embodiment or the like described above, the light-shielding part 124 formed in the separating regions may be made of metal such as tungsten (W) so that a hole accumulation region is formed near the light-shielding part 124 by the application of a voltage to the light-shielding part 124.

Further, in the first embodiment or the like described above, a structure in which the thickness (depth) of the well layer 103 is further increased may be employed. When such a structure is employed, a fixed charge film can be, for example, formed on the side of the lateral surfaces of the well layer 103 together with the formation of the light-shielding part 124 in the separating regions. Further, a hole accumulation region can also be formed in a part of the lateral surfaces of the well layer 103 of the fixed charge film.

In addition, in the first embodiment or the like described above, the n-type semiconductor region 101 may have another shape. For example, portions other than a portion to which the contact is connected are embedded in the well layer 103 to be formed, whereby the cross-sectional shape of the n-type semiconductor region 101 can be formed into a shape having a convex part. Note that the convex part can be continuously or discontinuously formed. Further, the flat shape of the n-type semiconductor region 101 in this case can be, for example, a ring shape.

Note that (the light-shielding part 124 of) the separating regions is formed to penetrate from the upper surface side to the lower surface side of the well layer 103 in a laminating direction in the first embodiment or the like described above. However, besides the structure in which the light-shielding part 124 entirely penetrates from the upper surface side to the lower surface side, a structure in which the (light-shielding part 124) of the separating regions partially penetrates and is inserted halfway through a substrate or the like may be employed.

(p-n Inversion)

Further, the polarities of the SPADs shown in the embodiments described above are given as an example, and the SPADs may have different polarities (that is, p-n inversion may be performed). For example, the n-type semiconductor region 101 and the p-type semiconductor region 102 are formed inside the well layer 103 in the first embodiment. However, a p-type semiconductor region 101 of which the conductivity type is p and an n-type semiconductor region 102 of which the conductivity type is n may be formed. Further, the well layer 103 may be a semiconductor region of which the conductivity type is n or a semiconductor region of which the conductivity type is p.

When such a structure is employed, the p-type semiconductor region 101 functions as an anode and is connected to the wiring 112 via the contact 111. Further, a cathode opposite to the anode is formed in, for example, the same layer as the p-type semiconductor region 101, the cathode being put in the place between the p-type semiconductor region 101 and (the light-shielding part 124 of) the separating regions or the like.

Note that the materials and the thickness or the film forming methods and the film forming conditions or the like of the respective layers described in the above embodiments are not limited to the above descriptions but other materials and thickness or other film forming methods and film forming conditions may be employed. Further, the configurations of the pixels 100 are specifically described in the above embodiments or the like. However, all the layers are not necessarily provided, or other layers may be further provided.

### 9. Application Example to Solid-State Imaging Device

In the above embodiments, the pixels 100 including the avalanche photodiodes (APDs), the single photon avalanche photodiodes (SPADs), or the photodiodes (PDs) are described. As shown in FIG. 20, the pixels 100 are arranged in an array shape in a pixel region A1 provided in a sensor chip 11 constituting a solid-state imaging device 10.

A logic chip (not shown) is connected to the lower surface (the surface on a side opposite to the light incident surface) of the sensor chip 11 in which the pixels 100 are arranged. In the logic chip, a circuit that processes signals from the pixels 100 or supplies power to the pixels 100 is formed.

A peripheral region A2 is arranged on the outside of the pixel region A1. In addition, a pad region A3 is arranged on the outside of the peripheral region A2.

In the pad region A3, pad opening parts that are holes in a vertical direction reaching the inside part of the wiring layer from the upper end of the sensor chip 11 and are holes for wiring to electrode pads are formed to be arranged side by side in a line. The peripheral region A2 provided between the pixel region A1 and the pad region A3 is constituted by an n-type semiconductor region and a p-type semiconductor region.

### 10. Application Example to Distance Measurement Device

The solid-state imaging device described above is applicable to a distance measurement device (ranging device) that measures a distance. FIG. 21 is a diagram showing a configuration example of a distance measurement device to which the present technology is applied.

A distance measurement device 1000 shown in FIG. 21 is configured to include a light pulse transmitter that serves as a light source, a light pulse receiver 1012 that serves as a light reception unit, and an RS flip flop 103.

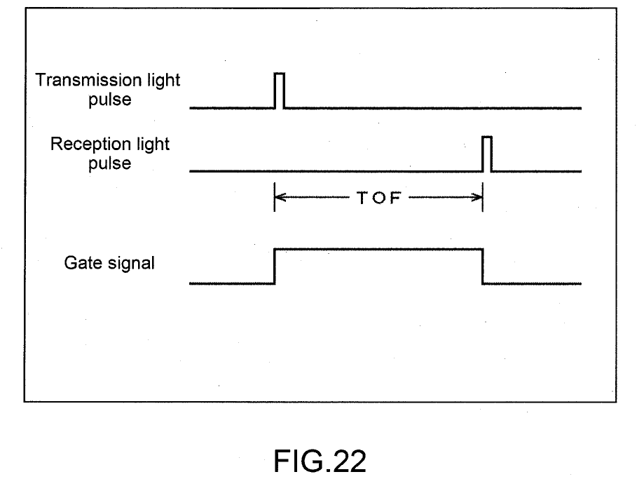

Here, a case in which a TOF (Time Of Flight) system is used will be exemplified as a method for measuring a distance. A TOF type sensor is a sensor that measures time until light emitted from the sensor itself reflects and returns after coming into contact with an object to measure a distance to the object. The TOF type sensor operates at, for example, a timing shown in the timing chart of FIG. 22.

The operation of the distance measurement device 1000 will be described with reference to FIG. 22. The light pulse transmitter 1011 emits light (transmission light pulse) on the basis of a trigger pulse supplied thereto. Then, light reflected after coming into contact with an object is received by the light pulse receptor 1012.

The difference between time at which the transmission light pulse is emitted and time at which a reception light pulse is received corresponds to time according to a distance to the object, that is, light flying time TOF.

The trigger pulse is supplied to the RS flip flop 103, while being supplied to the light pulse transmitter 1011. A short-time light pulse is transmitted when the trigger pulse is supplied to the light pulse transmitter 1011, and the RS flip flop 103 is reset when the trigger pulse is supplied to the RS flip flop 1013.

Here, the solid-state imaging device 10 (FIG. 20) having the pixels 100 including APDs such as SPADs can be, for example, used as the light pulse receiver 1012 constituting the TOF type sensor. When the solid-state imaging device 10 (FIG. 20) is used as the light pulse receiver 1012, a photon is generated as the reception light pulse is received by the pixels 100 including SPADs. The RS flip flop 1013 is reset by the generated photon (electric pulse).

By such an operation, a gate signal having a pulse width corresponding the light flight time TOF can be generated. By counting the generated gate signal with a clock signal or the like, the light flight time TOF can be calculated (output as a digital signal).

When such processing is performed, distance information is generated by the distance measurement device 1000. Then, a distance image can be obtained using, for example, the distance information.

### 11. Application Example to Mobile Bodies

The technology according to the present disclosure (the present technology) is applicable to various products. For example, the technology according to the present disclosure may be realized as an apparatus mounted on any type of moving objects such as an automobile, an electric car, a hybrid electric vehicle, a motorcycle, a bicycle, personal mobility, an airplane, a drone, a ship, and a robot.

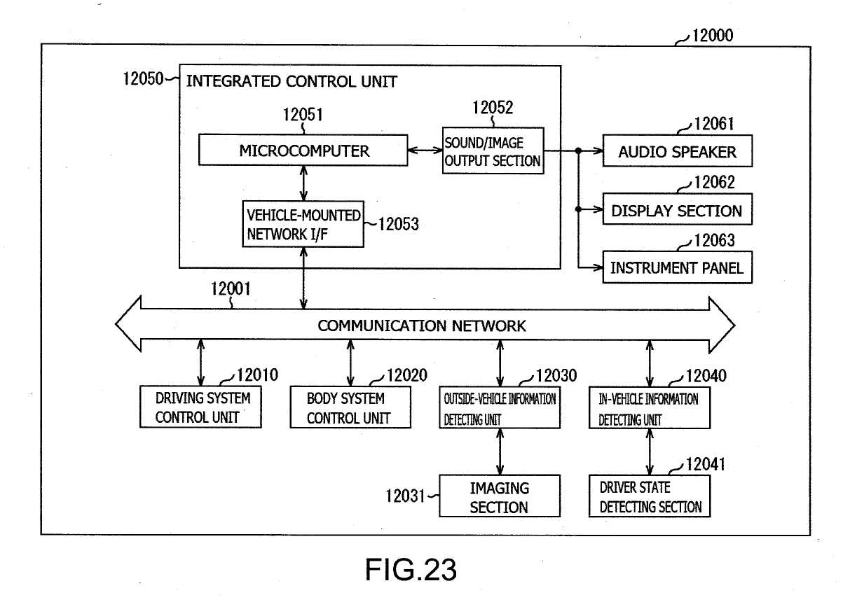

FIG. 23 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 23, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automatic driving, which makes the vehicle to travel autonomously without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 23, an audio speaker 12061, a display section 12062, and an instrument panel 12063 are illustrated as the output device. The display section 12062 may, for example, include at least one of an on-board display and a head-up display.

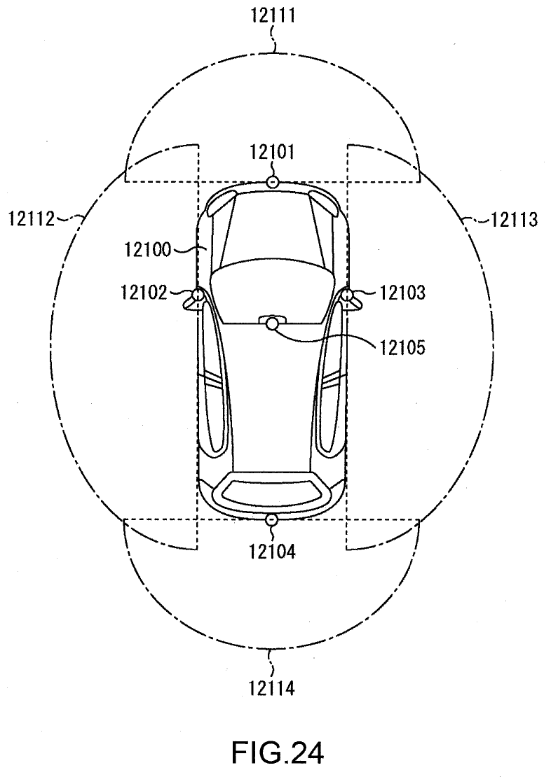

FIG. 24 is a diagram depicting an example of the installation position of the imaging section 12031.

In FIG. 24, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 24 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automatic driving that makes the vehicle travel autonomously without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology related to the present disclosure is applicable is described above. The technology related to the present disclosure is applicable to the imaging unit 12031 among the configurations described above. Specifically, the solid-state imaging device of FIG. 1 or the like (the distance measurement device of FIG. 21) is applicable to the imaging unit 12031. Since the imaging unit is allowed to improve condensing efficiency with the technology related to the present disclosure applied thereto, it becomes possible to acquire, for example, a more accurate captured image (distance image) and recognize an obstacle such as a pedestrian more exactly.

Note that the embodiments of the present technology are not limited to the embodiments described above but may be changed in various ways without departing from the spirit of the present technology.

Further, the present technology can employ the following configurations.

(1) A solid-state imaging device including:

a pixel unit in which a plurality of pixels each having a light detection unit are arranged;

a micro lens formed on a light incident surface side of the light detection unit for each of the pixels; and

a light-shielding unit that is formed around the micro lens and shields light, wherein

the micro lens is formed inside an opening part provided in the light-shielding part.

(2) The solid-state imaging device according to (1), wherein

the opening part has a circular shape, and

the micro lens is a spherical lens that is circular when seen from the light incident surface side and has a uniform curvature in a two-dimensional direction.

(3) The solid-state imaging device according to (1), wherein

the opening part has a polygonal shape, and

the micro lens is a lens having a polygonal shape when seen from the light incident surface side.

(4) The solid-state imaging device according to any of (1) to (3), wherein

the opening part is provided so that the micro lens is arranged at even intervals in a matrix direction when seen from the light incident surface side.

(5) The solid-state imaging device according to any of (1) to (3), wherein

the opening part is provided so that the micro lens is periodically arranged with an interval thereof narrowed when seen from the light incident surface side.

(6) The solid-state imaging device according to any of (1) to (5), wherein

the light detection unit is an avalanche photodiode (APD) or a single photon avalanche photodiode (SPAD).

(7) The solid-state imaging device according to any of (1) to (5), wherein

the light detection unit is a photodiode (PD).

(8) The solid-state imaging device according to (7), wherein

the pixel is an R pixel, a G pixel, or a B pixel.

(9) The solid-state imaging device according to (8), wherein

the opening part includes a first opening part having a prescribed diameter and a second opening part that is provided in a region other than a region in which the first opening part is provided and has a diameter smaller than the diameter of the first opening part,

a first micro lens formed inside the first opening part is formed with respect to the R pixel, the G pixel, or the B pixel, and

the second micro lens formed inside the second opening part is formed with respect to an IR pixel.

(10) The solid-state imaging device according to any of (1) to (6), wherein

the light-shielding part is made of metal and used as route wiring on the light incident surface side of the light detection unit.

(11) The solid-state imaging device according to any of (1) to (10), wherein

a reflection preventing film is formed on an upper part of the light-shielding part.

(12) The solid-state imaging device according to any of (1) to (9), wherein

the light-shielding part is made of metal or an insulating film.

(13) A distance measurement device including:

a pixel unit in which a plurality of pixels each having a light detection unit are arranged;

a micro lens formed on a light incident surface side of the light detection unit for each of the pixels; and

a light-shielding unit that is formed around the micro lens and shields light, wherein

the micro lens has a light reception unit formed inside an opening part provided in the light-shielding part.

(14) A manufacturing method for a solid-state imaging device, the manufacturing method including:

forming a pattern of a lens material inside an opening part provided in a light-shielding part; and

forming a micro lens in a self-aligning manner with an inner wall of the opening part as a stopper when the lens material formed inside the opening part is subjected to thermal reflow to form the micro lens.

### REFERENCE SIGNS LIST

10 solid-state imaging device
11 sensor chip
100 pixel
100L, 100S pixel
101 n type semiconductor region
102 p type semiconductor region
103 well layer
121 p type semiconductor region
122 p type semiconductor region
123 insulating film
124 light-shielding part
124C opening part
124O, 124Q opening part
124L, 124S opening part
131 reflection preventing film
132 insulating film
133 on-chip lens
133L, 133S on-chip lens
134 reflection preventing film
1000 distance measurement device
1011 light pulse transmitter
1012 light pulse receiver
1013 RS flip flop
12031 imaging unit

What is claimed is:

1. A solid-state imaging device comprising:
a pixel unit in which a plurality of pixels each having a light detection unit are arranged;
a micro lens formed on a light incident surface side of the light detection unit for each of the pixels; and
a light-shielding unit that is formed around the micro lens and shields light, wherein
the micro lens is formed inside an opening part provided in the light-shielding part.

2. The solid-state imaging device according to claim 1, wherein
the opening part has a circular shape, and
the micro lens is a spherical lens that is circular when seen from the light incident surface side and has a uniform curvature in a two-dimensional direction.

3. The solid-state imaging device according to claim 2, wherein
the opening part has a polygonal shape, and
the micro lens is a lens having a polygonal shape when seen from the light incident surface side.

4. The solid-state imaging device according to claim 1, wherein
the opening part is provided so that the micro lens is arranged at even intervals in a matrix direction when seen from the light incident surface side.

5. The solid-state imaging device according to claim 1, wherein
the opening part is provided so that the micro lens is periodically arranged with an interval thereof narrowed when seen from the light incident surface side.

6. The solid-state imaging device according to claim 2, wherein
the light detection unit is an avalanche photodiode (APD) or a single photon avalanche photodiode (SPAD).

7. The solid-state imaging device according to claim 2, wherein
the light detection unit is a photodiode (PD).

8. The solid-state imaging device according to claim 7, wherein
the pixel is an R pixel, a G pixel, or a B pixel.

9. The solid-state imaging device according to claim 8, wherein
the opening part includes a first opening part having a prescribed diameter and a second opening part that is provided in a region other than a region in which the first opening part is provided and has a diameter smaller than the diameter of the first opening part,
a first micro lens formed inside the first opening part is formed with respect to the R pixel, the G pixel, or the B pixel, and
the second micro lens formed inside the second opening part is formed with respect to an R pixel.

10. The solid-state imaging device according to claim 1, wherein
the light-shielding part is made of metal and used as route wiring on the light incident surface side of the light detection unit.

11. The solid-state imaging device according to claim 1, wherein
a reflection preventing film is formed on an upper part of the light-shielding part.

12. The solid-state imaging device according to claim 1, wherein
the light-shielding part is made of metal or an insulating film.

13. A distance measurement device comprising:
a pixel unit in which a plurality of pixels each having a light detection unit are arranged;
a micro lens formed on a light incident surface side of the light detection unit for each of the pixels; and
a light-shielding unit that is formed around the micro lens and shields light, wherein
the micro lens has a light reception unit formed inside an opening part provided in the light-shielding part.

14. A manufacturing method for a solid-state imaging device, the manufacturing method comprising:
forming a pattern of a lens material inside an opening part provided in a light-shielding part; and
forming a micro lens in a self-aligning manner with an inner wall of the opening part as a stopper when the lens material formed inside the opening part is subjected to thermal reflow to form the micro lens.
